(19) United States
(12) Patent Application Publication
(10) Pub. No.: US 2024/0151583 A1
(43) Pub. Date: May 9, 2024

(54) HYPERSPECTRAL SENSOR WITH PIXEL HAVING LIGHT FOCUSING TRANSPARENT DIFFRACTIVE GRATING

(71) Applicant: SONY SEMICONDUCTOR SOLUTIONS CORPORATION, Kanagawa (JP)

(72) Inventor: Victor A. Lenchenkov, Rochester, NY (US)

(73) Assignee: SONY SEMICONDUCTOR SOLUTIONS CORPORATION, Kanagawa (JP)

(21) Appl. No.: 17/983,680

(22) Filed: Nov. 9, 2022

(51) Int. Cl. G01J 3/28; G01J 3/02; G01J 3/18

(52) U.S. Cl. CPC G01J 3/2823; G01J 3/0208; G01J 3/18; G01J 2003/2826

(57) ABSTRACT

Wavelength determining image sensors and systems are provided. A sensor as disclosed includes a number of pixels disposed within an array, each of which includes a plurality of sub-pixels. Each wavelength sensing pixel within the image sensor is associated with a set of diffraction features disposed in a plurality of diffraction element layers. The diffraction features can be formed from materials having an index of refraction that is higher than an index of refraction of the surrounding material. At least one of the diffraction element layers is formed in a grating substrate on a light incident side of a sensor substrate. Wavelength information regarding light incident on a pixel is determined by applying ratios of signals obtained from pairs of included sub-pixels and calibrated ratios for different wavelengths to a set of equations. A solution to the set of equations provides the relative contributions of the calibrated wavelengths to the incident light.

### FIELD

The present disclosure relates to a hyperspectral sensor device with one or more pixels incorporating a light focusing transparent scattering diffractive grating to enable high color resolution and sensitivity.

### BACKGROUND

Digital image sensors are commonly used in a variety of electronic devices, such as scientific instruments, handheld cameras, security systems, telephones, computers, and tablets, to detect light. In a typical arrangement, light sensitive areas or pixels are arranged in a two-dimensional array having multiple rows and columns of pixels, and are operated to capture images. Each pixel generates an electrical charge in response to receiving photons as a result of being exposed to incident light. For example, each pixel can include a photodiode that generates charge in an amount that is generally proportional to the amount of light (i.e. the number of photons) incident on the pixel during an exposure period. The charge can then be read out from each of the pixels, for example through peripheral circuitry.

In conventional color image sensors, absorptive color filters are used to enable the image sensor to detect the color of incident light. The color filters are typically disposed in sets (e.g. of red, green, and blue (RGB); cyan, magenta, and yellow (CMY); or red, green, blue, and infrared (RGBIR)). Such arrangements have about 3-4 times lower sensitivity and signal to noise ratio (SNR) at low light conditions, color cross-talk, color shading at high chief ray angles (CRA), and lower spatial resolution due to color filter patterning resulting in lower spatial frequency as compared to monochrome sensors without color filters. However, the image information provided by a monochrome sensor does not include information about the color of the imaged object.

In addition, conventional color and monochrome image sensors incorporate non-complementary metal-oxide semiconductor (CMOS), polymer-based materials, for example to form filters and micro lenses for each of the pixels, resulting in image sensor fabrication processes that are more time-consuming and expensive than processes that only require CMOS materials. Moreover, the resulting devices suffer from compromised reliability and operational life, as the included color filters and micro lenses are subject to weathering and performance that degrades at a much faster rate than inorganic CMOS materials. In addition, the processing required to interpolate between pixels of different colors in order to produce a continuous image is significant.

Image sensors have been developed that utilize uniform, non-focusing metal gratings, to diffract light in a wavelength dependent manner, before that light is absorbed in a silicon substrate. Such an approach enables the wavelength characteristics (i.e. the color) of incident light to be determined, without requiring the use of absorptive filters. However, the non-focusing diffractive grating results in light loss before the light reaches the substrate. Such an approach also requires an adjustment or shift in the microlens and the grating position and structures across the image plane to accommodate high chief ray angles (CRAs).

Still other sensor systems that enable color to be sensed without the use of color filters are so called “color routers”, which direct light among a 2×2 Bayer array of red, green, green, and blue pixels. In such systems, instead of using absorptive filters to select the light that is incident on the individual pixels, the light is routed to the pixels within the Bayer array on the basis of color by high index of refraction diffractive elements. Although this avoids the loss inherent to absorptive filter designs, the resulting color resolution of the sensor is the same as or similar to that of a filter based Bayer array. In addition, determining the pattern of the diffractive elements used to route the light of different colors requires the use of artificial intelligence design procedures, and results in a relatively tall structure.

Accordingly, it would be desirable to provide an image sensor with high sensitivity and high wavelength resolution that could be produced more easily than previous devices.

### SUMMARY

Embodiments of the present disclosure provide image sensors, image sensing methods, and methods for producing image sensors that provide high wavelength resolution and sensitivity. An image sensor in accordance with embodiments of the present disclosure includes a sensor array having a plurality of pixels. Each pixel in the plurality of pixels includes a plurality of sub-pixels formed within a sensor substrate. In addition, each pixel is associated with a set of diffraction features. In accordance with embodiments of the present disclosure, each set of diffraction features includes a plurality of diffraction element layers. For example, each set of diffraction features can include four diffraction element layers. The first and second diffraction element layers can be disposed in a grating substrate adjacent a light incident surface of the sensor substrate. The third and fourth diffraction layers can be embedded into opposite surfaces of the sensor substrate. The diffraction elements can be formed from a transparent material having an index of refraction that is higher than an index of refraction of the material layer or substrate in which they are embedded.

The sets of diffraction elements can include grating lines or features that are radially distributed about a center line or area of an associated pixel. The pattern, line dimensions, and refractive index of the diffraction elements are configured to focus, diffract, or otherwise distribute incident light across the sub-pixels. The ratios of the signals generated in response to the incident light by the sub-pixels can then be used to determine the relative ratio of different wavelength components within that incident light. For example, the relative proportions or ratios of included wavelengths can be determined by solving a matrix of linear equations, with one linear equation for each of a plurality of calibrated wavelengths. As another example, a plurality of sets of linear equations, with one set of equations for each of a plurality of calibrated wavelengths, can be used to determine the relative proportion or ratio of included wavelengths. In accordance with further embodiments of the present disclosure, the wavelength composition of the signals can be used to determine the relative contributions of different wavelengths within the incident light with relatively high resolution (e.g. 25 nm) and over a hyperspectral range (e.g. 400 nm to 950 nm).

Accordingly, the diffraction pattern produced across the area of the pixel by the diffraction features is dependent on the color or wavelength of the incident light. As a result, the wavelength of the light incident on a pixel can be determined from ratios of relative signal intensities at each of the sub-pixels within the pixel. Embodiments of the present disclosure therefore provide a wavelength or color determining image sensor that does not require wavelength selective filters. In addition, embodiments of the present disclosure do not require micro lenses or infrared filters in order to provide high resolution images and high resolution wavelength identification. Moreover, although it is possible to provide a color router type structure in connection with embodiments of the present disclosure, a definitive assignment of different wavelengths to different pixels as provided by a typical color router is not required. The resulting wavelength determining image sensor thus has high sensitivity, high spatial resolution, high wavelength resolution, wide spectral range, a low stack height, relatively low complexity of diffraction element pattern, and can be manufactured using conventional CMOS processes.

An imaging device or apparatus in accordance with embodiments of the present disclosure incorporates an image sensor having a plurality of diffraction layers, with some of the diffraction layers disposed in a diffraction or grating substrate adjacent a light incident side of the sensor substrate, and with additional diffraction layers disposed adjacent surfaces of the sensor substrate. The sensor substrate includes an array of pixels, each of which includes a plurality of light sensitive areas or sub-pixels. The elements of the various diffraction layers can be configured as transparent diffraction features disposed in sets, with one set for each pixel. The diffraction features can be configured to focus and/or scatter the incident light by providing a higher effective index of refraction towards a center of an associated pixel, and a lower effective index of refraction towards a periphery of the associated pixel. For example, a density or proportion of a light incident area of a pixel covered by the diffraction features can be higher at or near the center of the pixel than it is towards the periphery. Moreover, the set of diffraction features associated with at least some of the pixels can be asymmetric relative to a center of the pixel. Accordingly, the diffraction features can operate as diffractive pixel micro lenses, which create asymmetric diffractive light patterns that are strongly dependent on the wavelength composition of incident light.

The relative distribution of the incident light amongst the sub-pixels of a pixel is determined by comparing the signal ratios. For example, in a configuration in which each pixel includes a 2×2 array of sub-pixels, there are six possible combinations of sub-pixel signal ratios that can be used to identify the color of light incident at the pixel. As another example, a 3×3 array of sub-pixels enables up to thirty-six unique combinations of sub-pixel signal ratios. Some or all of the possible combinations of sub-pixel (e.g. photodiode) signal ratios can be used to calibrate the pixel and can then be used in an operational mode to extract the included proportions of different wavelengths in light incident on the pixel. For example, by using twenty-three of the thirty-six possible combinations of signal ratios calibrated for twenty-three different wavelengths spanning a range of from 400 nm to 950 nm, embodiments of the present disclosure can be used to determine the wavelength composition of light incident on a given diffractive pixel with a resolution of 25 nm. More particularly, a series of twenty-three linear equations, one for each calibrated wavelength, can be solved to determine the presence of different wavelengths within the light incident on a pixel within a range of from 400 nm to 950 nm with a resolution of 25 nm. As another example, a system of twenty-three sets of linear equations, with one set for each calibrated wavelength, can be used to determine the wavelength composition of light incident on a pixel within a range of from 400 nm to 950 nm with a resolution of 25 nm. As can be appreciated by one of skill in the art after consideration of the present disclosure, such resolutions and ranges, as well as such numbers of requestions used in the solution, can be varied according to various considerations, including a desired range of wavelength sensitivity and a desired resolution of wavelength determination.

In particular, because the interference pattern produced by the diffraction elements strongly correlates with the wavelength of the incident light, the incident light wavelength can be identified with very high accuracy (e.g. within 25 nm or less). The identification or assignment of the wavelength of the incident light from the ratios of signals produced by the sub-pixels can be determined by comparing those ratios to pre-calibrated subpixel photodiode signal ratios (attributes) of the wavelength of incident light. The total signal of the pixel is calculated as a sum of all of the subpixel signals. The wavelength composition can be output as numeric values. Alternatively or in addition, a display or output of the identified color spectrum can be produced by converting the determined color of the incident light into RGB or RGBIR space.

An imaging device or apparatus incorporating an image sensor in accordance with embodiments of the present disclosure can include an imaging lens that focuses collected light onto an image sensor. The light from the lens is focused and diffracted onto pixels included in the image sensor by transparent diffraction features. More particularly, each pixel includes a plurality of sub-pixels, and is associated with a set of diffraction features. The diffraction features function to create an asymmetrical diffraction pattern across the sub-pixels. Differences in the strength of the signals at each of the sub-pixels within a pixel can be applied to determine a wavelength of the light incident on the pixel.

Imaging sensing methods in accordance with embodiments of the present disclosure include focusing light collected from within a scene onto an image sensor having a plurality of pixels disposed in an array. The light incident on each pixel is focused and diffracted by a set of diffraction features onto a plurality of included sub-pixels. The diffraction pattern produced by the diffraction features depends on the wavelength composition of the incident light. Accordingly, the amplitude of the signal generated by the incident light at each of the sub-pixels in each pixel can be read to determine the wavelength of that incident light. In accordance with embodiments of the present disclosure, the assignment of a wavelength to light incident on a pixel includes determining ratios of signal strengths produced by sub-pixels within the pixel, and solving a system of equations using calibrated ratios. The amplitude or intensity of the light incident on the pixel is the sum of all of the signals from the sub-pixels included in that pixel. An image sensor produced in accordance with embodiments of the present disclosure therefore does not require micro lenses for each pixel or wavelength selective filters, and provides high sensitivity over a range that can be coincident with the full wavelength sensitivity of the image sensor pixels.

Methods for producing an image sensor in accordance with embodiments of the present disclosure include applying conventional CMOS production processes to produce an array of pixels in an image sensor substrate in which each pixel includes a plurality of sub-pixels or photodiodes. As an example, the material of the sensor substrate is silicon (Si), and each sub-pixel is a photodiode formed therein. In addition, a thin layer of material, referred to herein as a grating substrate, is disposed on or adjacent a light incident side of the sensor substrate. As an example, the thin layer of material is silicon oxide (SiO₂), and has a thickness of 500 nm or less. Each pixel can be associated with a set of diffraction elements, which can be distributed within multiple diffraction layers. For example, each set of diffraction elements for each pixel can include two layers of diffraction elements formed in the grating substrate, and two layers of diffraction elements formed in the sensor substrate. In accordance with the least some embodiments of the present disclosure, an anti-reflection layer can be disposed between the light incident surface of the image sensor substrate and the thin layer of material. The diffraction elements can be formed as transparent elements having a relatively high index of refraction features relative to the surrounding substrate material. For example, the diffraction elements can be formed from silicon nitride (SiN). Moreover, the diffraction elements can be of varying lengths, with a width of about 100 nm and a depth of about 150 nm, and the pattern can include a plurality of lines of various lengths disposed asymmetrically about and a center of a pixel. Moreover, the diffraction elements can extend along lines radiating from the center of the associated pixel. Notably, production of an image sensor in accordance with embodiments of the present disclosure can be accomplished using only CMOS processes. Moreover, an image sensor produced in accordance with embodiments of the present disclosure does not require micro lenses or color filters for each pixel.

Additional features and advantages of embodiments of the present disclosure will become more readily apparent from the following description, particularly when considered together with the accompanying drawings.

### BRIEF DESCRIPTION OF THE DRAWINGS

FIG. 1 depicts elements of a wavelength sensing image sensor in accordance with embodiments of the present disclosure;

FIG. 2 is a plan view of a portion of an exemplary color sensing image sensor in accordance with the prior art;

FIG. 3 is a cross section of a portion of an exemplary color sensing image sensor in accordance with the prior art;

FIG. 4 is a graph depicting the sensitivity to light of different wavelengths of an exemplary image sensor in accordance with the prior art;

FIG. 5 depicts components of a system incorporating a wavelength sensing image sensor in accordance with embodiments of the present disclosure;

FIG. 6 is a perspective view of a pixel included in a wavelength sensing image sensor in accordance with embodiments of the present disclosure;

FIG. 7 is a cross-section in elevation of the example pixel of FIG. 6;

FIGS. 8A-8D are top plan views of the respective diffraction layers included in the example pixel of FIG. 6;

FIGS. 9A-9B depict the diffraction of light by a set of diffractive elements across the sub-pixels of the example pixel of FIG. 6;

FIG. 10 is a perspective view of a pixel included in a wavelength sensing image sensor in accordance with other embodiments of the present disclosure;

FIG. 11 is a cross-section in elevation of the example pixel of FIG. 10;

FIGS. 12A-12D are top plan views of the respective diffraction layers of the example pixel of FIG. 10;

FIG. 13 depicts the diffraction of light by a set of diffractive elements across the sub-pixels of a pixel included in a color sensing image sensor in accordance with embodiments of the present disclosure;

FIGS. 14A-14B are plan views of pixels with examples of alternative sub-pixel arrangements in accordance with embodiments of the present disclosure;

FIG. 15 depicts aspects of a process for calibrating a pixel of an image sensor in accordance with embodiments of the present disclosure;

FIG. 16 is an example of recorded pixel ratio values obtained through a calibration process in accordance with embodiments of the present disclosure;

FIG. 17 depicts aspects of a process for determining a wavelength of light incident on an image sensor pixel in accordance with embodiments of the present disclosure;

FIG. 18 depicts aspects of a process for calibrating a pixel of an image sensor in accordance with other embodiments of the present disclosure;

FIG. 19 depicts aspects of a process for determining a wavelength of light incident on an image sensor pixel in accordance with other embodiments of the present disclosure; and

FIG. 20 is a block diagram illustrating a schematic configuration example of a camera that is an example of a device including an image sensor in accordance with embodiments of the present disclosure.

### DETAILED DESCRIPTION

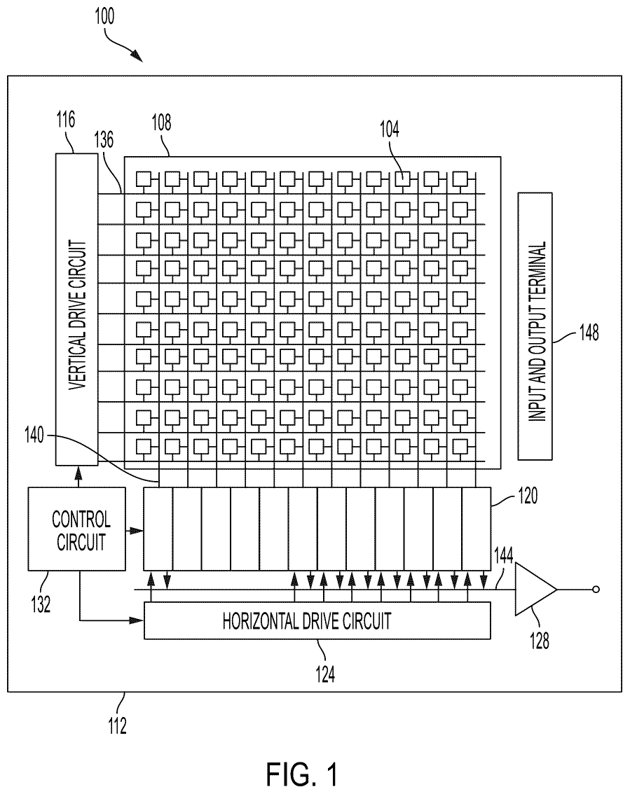

FIG. 1 is a diagram that depicts elements of a wavelength sensing image sensor or device 100 in accordance with embodiments of the present disclosure. In general, the wavelength sensing image sensor 100 includes a plurality of pixels 104 disposed in an array 108. More particularly, the pixels 104 can be disposed within an array 108 having a plurality of rows and columns of pixels 104. Moreover, the pixels 104 are formed in a sensor substrate 112. In addition, one or more peripheral or other circuits can be formed in connection with the sensor substrate 112. Examples of such circuits include a vertical drive circuit 116, a column signal processing circuit 120, a horizontal drive circuit 124, an output circuit 128, and a control circuit 132. As described in greater detail elsewhere herein, each of the pixels 104 within a color sensing image sensor 100 in accordance with embodiments of the present disclosure includes a plurality of photosensitive sites or sub-pixels.

The control circuit 132 can receive data for instructing an input clock, an operation mode, and the like, and can output data such as internal information related to the image sensor 100. Accordingly, the control circuit 132 can generate a clock signal that provides a standard for operation of the vertical drive circuit 116, the column signal processing circuit 120, and the horizontal drive circuit 124, and control signals based on a vertical synchronization signal, a horizontal synchronization signal, and a master clock. The control circuit 132 outputs the generated clock signal in the control signals to the various other circuits and components.

The vertical drive circuit 116 can, for example, be configured with a shift register, can operate to select a pixel drive wiring 136, and can supply pulses for driving sub-pixels of a pixel 104 through the selected drive wiring 136 in units of a row. The vertical drive circuit 116 can also selectively and sequentially scan elements of the array 108 in units of a row in a vertical direction, and supply the signals generated within the pixels 104 according to an amount of light they have received to the column signal processing circuit 120 through a vertical signal line 140.

The column signal processing circuit 120 can operate to perform signal processing, such as noise removal, on the signal output from the pixels 104. For example, the column signal processing circuit 120 can perform signal processing such as a correlated double sampling (CDS) for removing a specific fixed patterned noise of a selected pixel 104 and an analog to digital (A/D) conversion of the signal.

The horizontal drive circuit 124 can include a shift register. The horizontal drive circuit 124 can select each column signal processing circuit 120 in order by sequentially outputting horizontal scanning pulses, causing each column signal processing circuit 122 to output a pixel signal to a horizontal signal line 144.

The output circuit 128 can perform predetermined signal processing with respect to the signals sequentially supplied from each column signal processing circuit 120 through the horizontal signal line 144. For example, the output circuit 128 can perform a buffering, black level adjustment, column variation correction, various digital signal processing, and other signal processing procedures. An input and output terminal 148 exchanges signals between the image sensor 100 and external components or systems.

Accordingly, at least portions of a color sensing image sensor 100 in accordance with at least some embodiments of the present disclosure can be configured as a CMOS image sensor of a column A/D type in which column signal processing is performed.

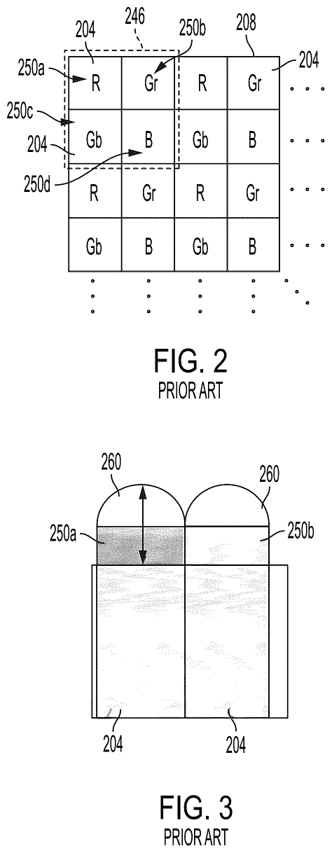

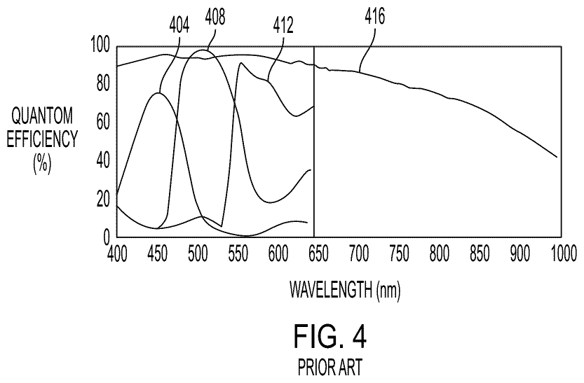

With reference now to FIGS. 2 and 3, portions of a pixel array 208 of an exemplary color sensing image sensor in accordance with the prior art are depicted. FIG. 2 shows a portion of the pixel array 208 in a plan view, and illustrates how individual pixels 204 are disposed in 2×2 sets 246 of four pixels 204. In this particular example, each 2×2 set 246 of four pixels 204 is configured as a so-called Bayer array, in which a first one of the pixels 204 is associated with a red color filter 250a, a second one of the pixels 204 is associated with a green color filter 250b, a third one of the pixels 204 is associated with another green color filter 250c, and fourth one of the pixels 204 is associated with the blue color filter 250d. FIG. 3 illustrates a portion of the pixel 204 encompassing one such Bayer array in cross section, and additionally depicts micro lenses 260 that function to focus light onto an associated pixel 204. In such a configuration, each individual pixel 204 is only sensitive to a portion of the visible spectrum. As a result, the spatial resolution of the image sensor is reduced as compared to monochrome sensors. Moreover, because the light incident on the photosensitive portion of each pixel 204 is filtered, sensitivity is lost. This is illustrated in FIG. 4, which includes lines 404, 408, and 412, corresponding to the sensitivity of pixels associated with blue, green and red filters 250 respectively, and also with an infrared-cut filter. For comparison, the sensitivity of a monochrome sensor that is not associated with any filters is shown at line 416. In addition to the various performance issues, conventional color and monochrome image sensors have a relatively high stack height, and typically incorporate non-CMOS polymer-based materials, which adds costs to the manufacturing process, and results in a device that is less reliable and that has a shorter lifetime, as color filters 250 and micro lenses 260 are subject to weathering and to performance that degrades more quickly than inorganic CMOS materials.

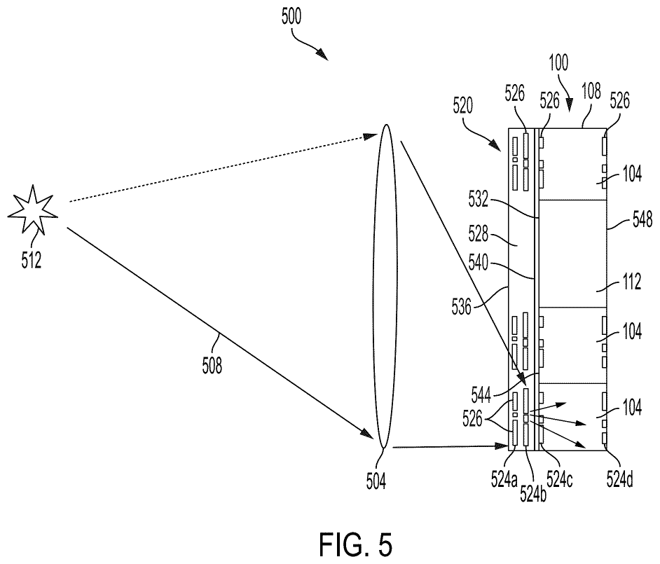

FIG. 5 depicts components of a system 500 incorporating a wavelength sensing image sensor 100 in accordance with embodiments of the present disclosure, including a cross section view of elements of the pixel array 108 of the wavelength sensing image sensor 100. As shown, the system 500 can include an optical system 504 that collects and focuses light from within a field of view of the system 500, including light 508 reflected or otherwise received from an object 512 within the field of view of the system 500, onto pixels 104 included in the pixel array 108 of the image sensor 100. As can be appreciated by one of skill in the art after consideration of the present disclosure, the optical system 504 can include a number of lenses, mirrors, apertures, shutters, filters or other elements. In accordance with embodiments of the present disclosure, the pixel array 108 includes an imaging or sensor substrate 112 in which the pixels 104 of the array 108 are formed. In addition, a plurality of sets of diffraction features or elements 520 are included, with one set of diffraction features 520 provided for each pixel 104 within the array 108. Diffraction elements 526 within each set of diffraction features 520 can be disposed in a plurality of diffraction element layers 524 (four of which are shown in the example of FIG. 5 as diffraction element layers 524a-d). In addition, an anti-reflective coating 532 can be disposed between the light incident surface side of the sensor substrate 112 and a grating substrate 528.

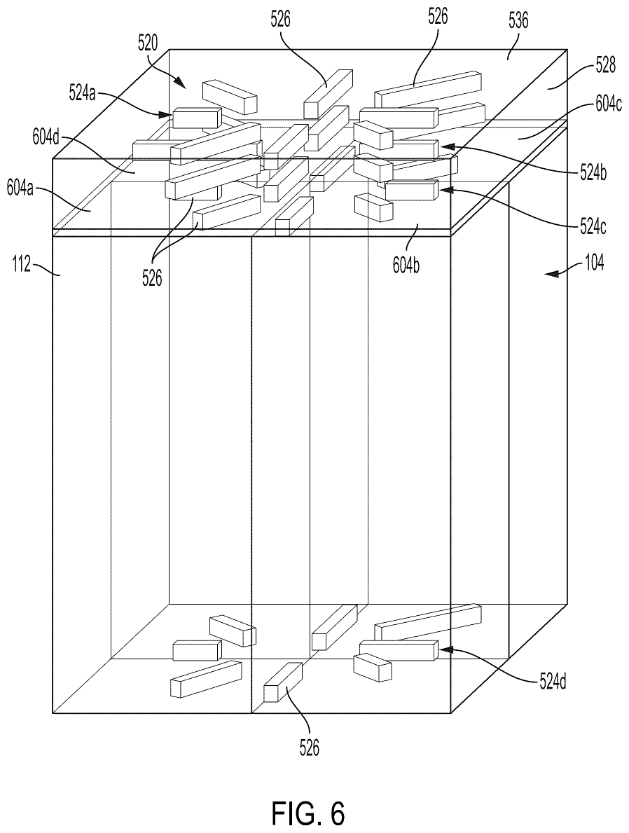

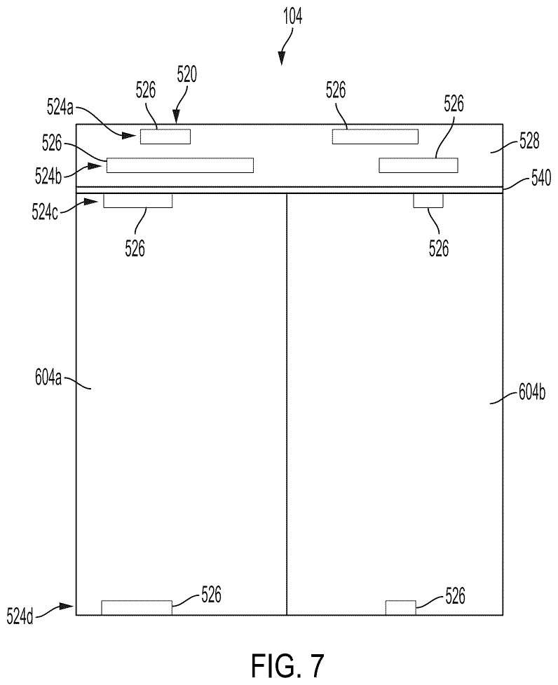

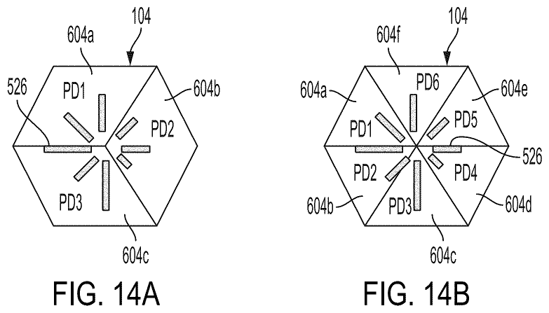

FIGS. 6 and 7 are perspective and cross section in elevation views respectively of a pixel 104 included in a wavelength sensing image sensor in accordance with embodiments of the present disclosure. As shown, each pixel 104 within the array 108 includes a plurality of sub-pixels 604. The sub-pixels 604 within a pixel 104 can be formed as adjacent photoelectric conversion elements or areas within the image sensor substrate 112. In operation, each sub-pixel 604 generates a signal in proportion to an amount of light incident thereon. As an example, each sub-pixel 604 is a separate photodiode. As represented in FIGS. 6 and 7, each pixel 104 can include four sub-pixels 604a-d, with each of the sub-pixels 604 having an equally sized, square-shaped light incident surface. However, embodiments of the present disclosure are not limited to such a configuration, and can instead have any number of sub-pixels 604, with each of the sub-pixels 604 having the same or different shape, and/or the same or different size, as other sub-pixels 604 within the pixel 104. For example, each pixel 104 can include three sub-pixels 604a-c of the same size and a quadrilateral shape, placed together to form a pixel 104 having a hexagonal shape (FIG. 14A); or each pixel 104 can be comprised of six sub-pixels 604a-f having the same size and a triangular shape pieced together to form a pixel 104 with a hexagonal shape (FIG. 14B). In accordance with still other embodiments of the present disclosure, different pixels 104 can have different shapes sizes and configurations of included sub-pixels 604.

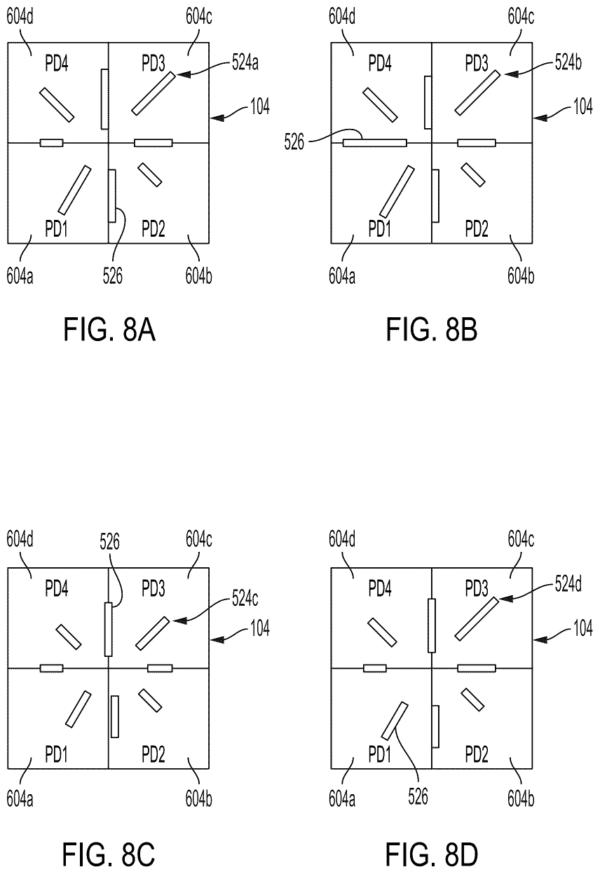

Each set of diffraction features 520 includes multiple diffraction element layers 524 that in turn include multiple diffraction elements 526. Examples of dispositions of diffraction elements within different diffraction element layers 524 are illustrated in plan view in FIGS. 8A-8D. In particular, FIG. 8A illustrates a first diffraction element layer 524a, FIG. 8B illustrates a second diffraction element layer 524b, FIG. 8C illustrates a third diffraction element layer 524c, and FIG. 8D illustrates a fourth diffraction element layer 524d, As shown, the different diffraction element layers 524 can differ in the sizing and disposition of included diffraction elements 526. Although the example diffraction element layers 524 of FIGS. 8A-8D each include the same number and general disposition of diffraction elements 526, other embodiments can have different numbers and/or dispositions of diffraction elements 526.

In accordance with embodiments of the present disclosure, one or more of the diffraction element layers 524 are formed in the grating substrate 528 that is disposed on a light incident surface side 536 of the sensor substrate 112, and one or more of the diffraction element layers 524 are formed in the sensor substrate 112. In the illustrated example, a first layer of diffraction elements 524a is disposed at or adjacent to a first or light incident surface side 536 of the grating substrate 528; a second layer of diffraction elements 524b is disposed at or adjacent a second surface side 540 of the grating substrate 528 that is surface opposite to the first surface side 536; a third layer of diffraction elements 524c is disposed at or adjacent a first or light incident surface side 544 of the sensor substrate 112; and a fourth layer of diffraction elements 524d is disposed at or adjacent a second surface side 548 of the sensor substrate 112 that is a surface opposite to the first surface side 544.

The diffraction elements 526 within each diffraction element layer 524 can be configured as linear elements each having a longitudinal extent that is disposed radially about a center point of an associated pixel 104. In accordance with embodiments of the present disclosure, every set of diffraction features 520 can be identical to one another. In accordance with other embodiments of the present disclosure, at least some of the sets of diffraction features 520 can be shifted according to a location of an associated pixel 104 within the array 108, such that a center point of the pattern coincides with a chief ray angle of incident light at that pixel 104. In accordance with still other embodiments, different patterns or configurations of diffraction elements 526 can be associated with different pixels 104 within an image sensor 100. For example, each pixel 104 can be associated with a different pattern of diffraction features 524. As another example, a particular diffraction element 526 pattern can be used for all of the pixels 104 within all or selected regions of the array 108. As a further example, differences in diffraction feature 524 patterns can be distributed about the pixels 104 of an image sensor randomly. Alternatively or in addition, different diffraction element 526 patterns can be selected so as to provide different focusing or diffraction characteristics at different locations within the array 108 of pixels 104. For instance, aspects of a diffraction element 526 pattern can be altered based on a distance of a pixel associated with the pattern from a center of the array 108.

In accordance with embodiments of the present disclosure, each of the diffraction elements 526 is transparent, and has an index of refraction that is lower or higher than an index of refraction of the substrate 112 or 528 in which the diffraction element 526 is formed. As examples, where the grating substrate 528 is SiO2 with a refractive index n of about 1.46, the diffraction elements 526 disposed therein (e.g. the diffraction elements 526 in the first 524a and second 524b diffraction element layers) can be formed from SiN, TiO2, HfO2, Ta2O5, or SiC with a refractive index n of from about 2 to about 2.6. Where the image substrate is Si, the diffraction elements 526 disposed therein (e.g. the diffraction elements 526 in the third 524c and fourth 524d diffraction element layers) can be formed from SiO2. Where a pixel 104 has an area of 1.4 um by 1.4 um, with four 700 nm sub-pixels 604 in a 2×2 array, the grating substrate 528 can be 150 nm thick, the anti-reflective coating 532 can be about 55 nm thick, and the diffraction elements 526 can have a width of 100 nm, a thickness (or height) of 150 nm, and a length of between 150 nm and 500 nm. Therefore, the features provided on the light incident surface side 544 can present a relatively low stack height of about 350 nm.

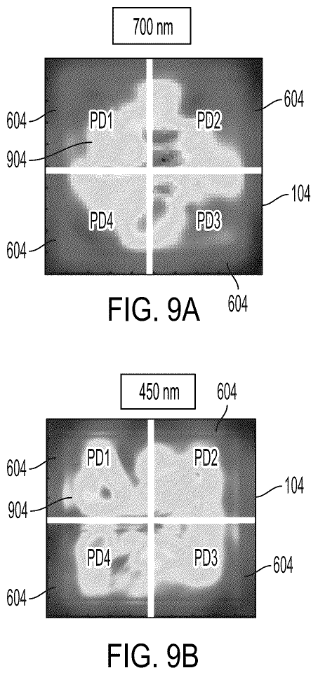

As previously noted, a set of diffraction features 520 is provided for each pixel 104, with the diffraction elements 526 of each set 520 distributed in multiple layers 524 of diffraction elements 526. The diffraction elements 526 are configured to focus and diffract incident light. Moreover, as depicted in FIGS. 9A and 9B light of different wavelengths can produce different distribution patterns across the sub-pixels 604 of a pixel 104. For example, in FIG. 9A, a distribution 904 of light having a wavelength of 700 nm by a set of diffraction features 520 is depicted, and in FIG. 9B, a distribution 904 of light having a wavelength of 450 nm by that same set of diffraction features 520 is depicted. However, the set of diffraction features 520 for a pixel 104 in accordance with embodiments of the present disclosure is not required to distribute light within distinct wavelength bands (e.g. according to color) across the sub-pixels 604. As a result, the diffraction elements 526 in accordance with embodiments of the present disclosure can be configured according to a simpler pattern as compared to the diffraction features of a color router.

In accordance with embodiments of the present disclosure, the different distributions 904 of light of different wavelengths across the different sub-pixels 604 of a pixel 104 allows the wavelength of the light incident of the pixel 104 to be determined. In particular, the differences in the amount of light incident on the different sub-pixels 604 results in the generation of different signal amounts by those sub-pixels 604. In particular, the different distributions 904 of light across the sub-pixels 604 of a pixel 104 for the light of different wavelengths results in different signal amplitudes from the different sub-pixels 604. These differences can be expressed as a number of different sub-pixel 604 pair signal ratios. As can be appreciated by one of skill in the art after consideration of the present disclosure, taking the ratios of the signals from each unique pair of sub-pixels 604 within a pixel 104 allows the distribution pattern 904 to be characterized consistently, even when the intensity of the incident light varies. Moreover, this simplifies the determination of the color associated with the detected distribution pattern 904 by producing normalized values. Thus, a set of signal ratios for a particular wavelength of light in the applies for any intensity of incident light.

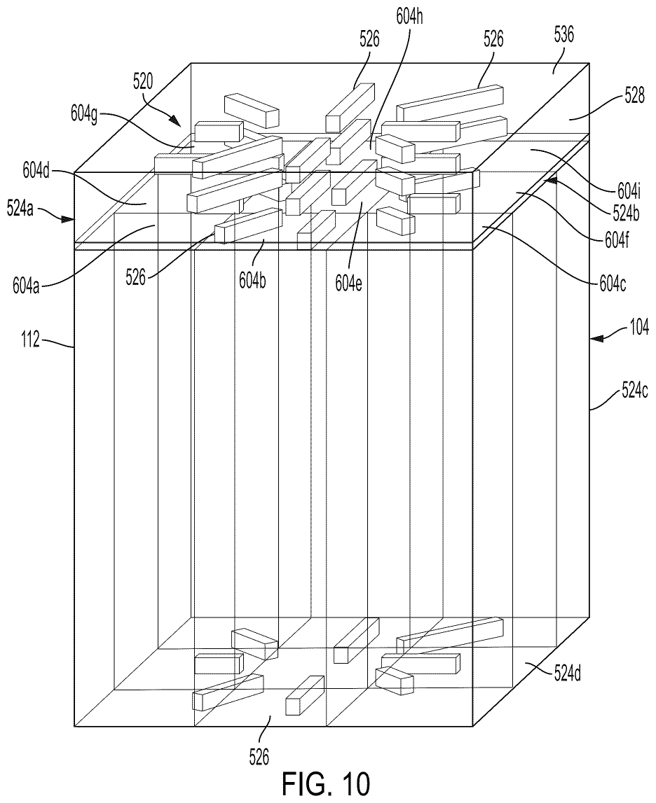

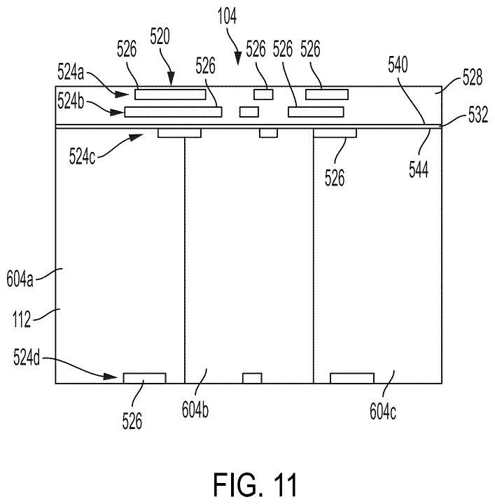

FIGS. 10 and 11 are perspective and cross section in elevation views respectively of a pixel 104 included in a wavelength sensing image sensor in accordance with further embodiments of the present disclosure. In this example embodiment, each pixel 104 within the array 108 includes nine sub-pixels 604a-i, disposed in a 3×3 array. As in other embodiments, the sub-pixels 604 within such a pixel 104 can be formed as adjacent photoelectric conversion elements or areas within the image sensor substrate 112 that operate to generate a signal in proportion to an amount of light incident thereon. Accordingly, as an example, each sub-pixel 604 can be provided as a separate photodiode. Each of the sub-pixels 604 can have an equally sized, square-shaped light incident surface. However, embodiments of the present disclosure are not limited to such a configuration, and can instead have any number of sub-pixels 604, with each of the sub-pixels 604 having the same or different shape, and/or the same or different size, as other sub-pixels 604 within the pixel 104. In accordance with still other embodiments of the present disclosure, different pixels 104 can have different shapes sizes and configurations of included sub-pixels 604.

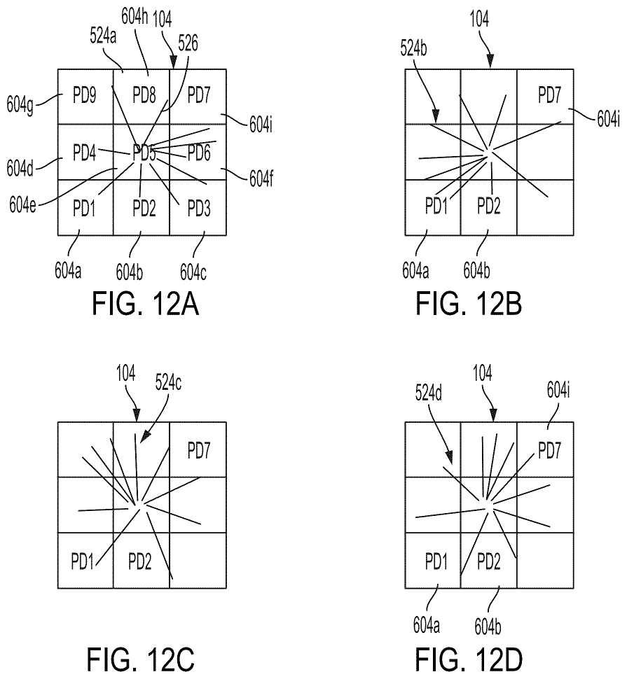

As in other embodiments, a pixel 104 includes a set of diffraction features 520. Each set of diffraction features 520 includes multiple diffraction element layers 524 that in turn include multiple diffraction elements 526. Further examples of dispositions of diffraction elements within different diffraction element layers 524 associated with a pixel 104 in accordance with embodiments of the present disclosure are illustrated in plan view in FIGS. 12A-12D. In particular, in FIG. 12A illustrates a first diffraction element layer 524a, FIG. 12B illustrates a second diffraction element layer 524b, FIG. 12C illustrates a third diffraction element layer 524c, and FIG. 12D illustrates a fourth diffraction element layer 524d. In this example, the pixel 104 includes nine sub-pixels 604, with the diffraction elements 526 within the diffraction element layers 524 centered about a center axis or about an expected chief ray angle for the pixel. Moreover, the different diffraction element layers 524 can differ in the sizing and disposition of included diffraction elements 526. Although the example diffraction element layers 524 of FIGS. 12A-12D each include the same number and general disposition of diffraction elements 526, other embodiments can have different numbers and/or dispositions of diffraction elements 526.

As in other embodiments of the present disclosure, one or more of the diffraction element layers 524 in the embodiment depicted in FIGS. 10-12 are formed in the grating substrate 528 that is disposed on a light incident surface side of the sensor substrate 112, and one or more of the diffraction element layers 524 are formed in the sensor substrate 112. In the illustrated example, a first layer of diffraction elements 524a is disposed at or adjacent to a first or light incident surface side 536 of the grating substrate 528; a second layer of diffraction elements 524b is disposed at or adjacent a second surface side 540 of the grating substrate 528 that is surface opposite to the first surface side 536; a third layer of diffraction elements 524c is disposed at or adjacent a first or light incident surface side 544 of the sensor substrate 112; and a fourth layer of diffraction elements 524d is disposed at or adjacent a second surface side 548 of the sensor substrate 112 that is a surface opposite to the first surface side 544. Moreover, a pixel 104 in accordance with embodiments of the present disclosure can include a set of diffraction features 520 with a greater or lesser number of diffraction element layers 524. For instance, the fourth diffraction element layer 524d can be omitted. Other distributions of diffraction element layers 524 within a pixel 104 are also possible. For instance, a pixel 104 can have a set of diffraction features 520 that includes first and second diffraction element layers 524 in the grating substrate 528, and that includes third and fourth diffraction element layers 524 in the sensor substrate 112 that are both adjacent to (e.g. within 350 nm of) the light incident surface side 544 of the sensor substrate 112.

As in or similar to other embodiments, the diffraction elements 526 within each diffraction element layer 524 of a pixel having nine sub-pixels 604 can be configured as linear elements each having a longitudinal extent that is disposed radially about a center point of an associated pixel 104. In accordance with embodiments of the present disclosure, every set of diffraction features 520 can be identical to one another. In accordance with other embodiments of the present disclosure, at least some of the sets of diffraction features 520 can be shifted according to a location of an associated pixel 104 within the array 108, such that a center point of the pattern coincides with a chief ray angle of incident light at that pixel 104. In accordance with still other embodiments, different patterns or configurations of diffraction elements 526 can be associated with different pixels 104 within an image sensor 100. For example, each pixel 104 can be associated with a different pattern of diffraction elements 526. As another example, a particular diffraction element 526 pattern can be used for all of the pixels 104 within all or selected regions of the array 108. As a further example, differences in diffraction element 526 patterns can be distributed about the pixels 104 of an image sensor randomly. Alternatively or in addition, different diffraction element 526 patterns can be selected so as to provide different focusing or diffraction characteristics at different locations within the array 108 of pixels 104. For instance, aspects of a diffraction element 526 pattern can be altered based on a distance of a pixel associated with the pattern from a center of the array 108.

Also as in or similar to other embodiments of the present disclosure, each of the diffraction elements 526 in the example of FIGS. 10-12 is transparent, and has an index of refraction that is higher than an index of refraction of the substrate 112 or 528 in which the diffraction element 526 is formed. As examples, where the grating substrate 528 is SiO2 with a refractive index n of about 1.46, the diffraction elements 526 disposed therein (e.g. the diffraction elements 526 in the first 524a and second 524b diffraction element layers) can be formed from SiN, TiO2, HfO2, Ta2O5, or SiC with a refractive index n of from about 2 to about 2.6. Where the image substrate is Si, the diffraction elements 526 disposed therein (e.g. the diffraction elements 526 in the third 524c and fourth 524d diffraction element layers) can be formed from SiO2. Where a pixel 104 has an area of 1.4 um by 1.4 um, with four 700 nm sub-pixels 604 in a 2×2 array, the grating substrate 528 can be 150 nm thick, the anti-reflective coating 532 can be about 55 nm thick, and the diffraction elements 526 can have a width of 100 nm, a thickness (or height) of 150 nm, and a length of between 150 nm and 500 nm. Therefore, the features provided on the light incident surface side 544 can present a relatively low stack height of about 350 nm.

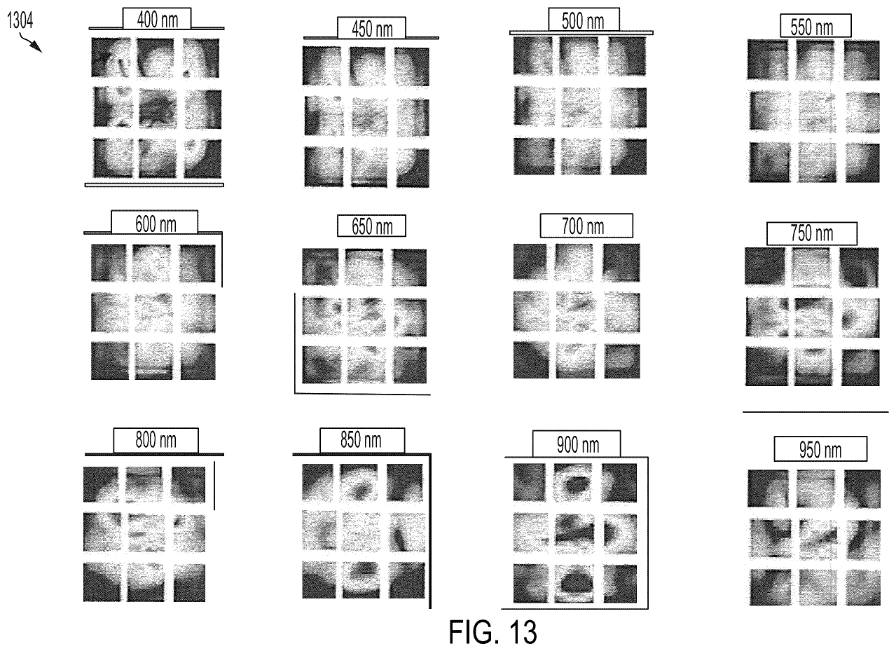

The interaction of light of different wavelengths with a set of diffraction features 520 of a pixel 104 can produce different distribution patterns across the sub-pixels 604 of that pixel 104. This is illustrated in FIG. 13, which depicts different distributions 1304 of light at wavelengths from 400 nm to 950 nm across the sub-pixels 604 of a pixel 104 by the set of diffraction features 520 associated with that pixel 104. As discussed in greater detail elsewhere herein, the different distribution patterns produce different signal amounts in the different sub-pixels 604. These differences can be expressed as a number of different sub-pixel 604 pair signal ratios for different wavelengths. Moreover, embodiments of the present disclosure providing a relatively large number of sub-pixels 604 can be calibrated to distinguish a relatively large number of wavelengths. For example, within a range of 400 nm to 950 nm, light at wavelength intervals of 25 nm can be distinguished if at least 23 sub-pixel 604 signal ratios have been calibrated. In particular, a pixel 104 with nine sub-pixels 604 provides as many as 36 sub-pixel 604 signal combinations or ratios. Accordingly, a pixel 104 with nine sub-pixels 604 is capable of providing color identification resolutions within a range of from 400 nm to 950 nm of even greater than 25 nm. As in other embodiments, taking the ratios of the signals from a number of unique pairs of sub-pixels 604 within a pixel 104 allows the distribution pattern 904 to be characterized consistently, even when the intensity of the incident light varies. Moreover, this simplifies the determination of the color associated with the detected distribution pattern 1304 by producing normalized values. Thus, a set of signal ratios obtained for a particular wavelength of light applies for any intensity of incident light.

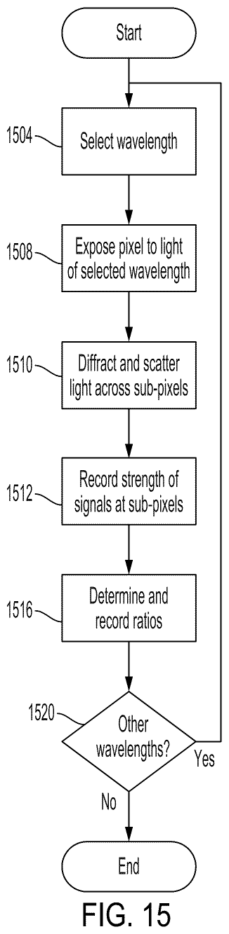

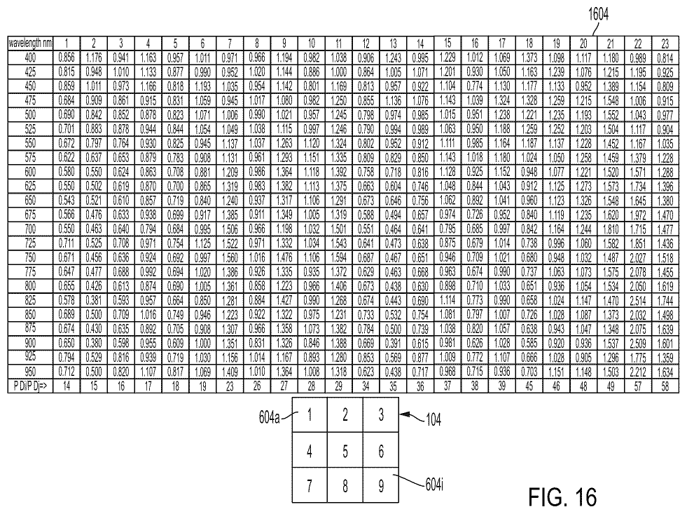

With reference now to FIG. 15, aspects of a method for calibrating the pixels 104 of an image sensor 100 having sets of diffraction features 520 in accordance with embodiments of the present disclosure, to enable the wavelength of light incident on the different pixels 104 to be determined, are presented. More particularly, in a pixel 104 having a 2×2 sub-pixel 604 configuration, six combinations of photodiode signal ratios are possible. In a pixel 104 having a 3×3 sub-pixel 604 configuration, thirty-six combinations of photodiode signal ratios are possible. By measuring the signal ratios of at least twenty-three of the possible combinations of the twelve sub-pixels 604 in a pixel 104 having a 3×3 sub-pixel 604 configuration, it is possible to measure a wavelength of incident light within a spectral range of from 400 nm to 950 nm with a resolution of 25 nm. The calibration process includes selecting a wavelength for calibration (step 1504) and exposing a pixel 104 to incident light having the selected wavelength (step 1508). For example, the pixel 104 may be exposed to 450 nm light. The incident light is diffracted and scattered across the sub-pixels 604 of the pixel 104 by the associated set of diffraction features 520 (step 1510). The strength of the signals produced at each of the sub-pixels 604 is then recorded (step 1512). At step 1516, ratios of sub-pixel 604 signal strengths are determined from the collected values and recorded. Where the sensor 100 is being calibrated to distinguish between wavelengths within a spectral range of 400 nm to 950 nm, and where a wavelength resolution of 25 nm is desired, twenty-three ratios are determined. As an example, following a pattern of notation where R14 is the ratio of the signal from sub-pixel 1 604a to the signal from sub-pixel 4 604d, these ratios can be as follows: R14; R15; R16; R17; R18; R19; R23; R26; R27; R28; R29; R34; R35; R36; R37; R38; R39; R45; R46; R48; R49; R57; R58. Recording the obtained ratio values can include placing them in a table 1204, for example as illustrated in FIG. 16.

At step 1520, a determination is made as to whether different wavelengths remain to be calibrated. If additional wavelengths remain to be calibrated, the process returns to step 1504, where a next wavelength is selected. The pixel 104 can then be exposed to incident light having the next selected wavelength (step 1508), the light is diffracted and scattered across the sub-pixels 604 of the pixel 104 (step 1510), the strength of the signals produced at each of the sub-pixels 604 is recorded (step 1512), and the selected ratios of sub-pixel 604 signal strengths are determined and recorded (step 1516). For example, the process can proceed in steps of 25 nm. Accordingly, after exposing the pixel 104 to light of a particular wavelength (e.g. 400 nm) and determining and recording the ratios of signal strengths, the pixel 104 can be exposed to light a the prior wavelength plus 25 nm (e.g. 425 nm) After a determination is made at step 1520 that subpixel 604 signal strength ratios for all of the desired wavelengths have been obtained, the table 1604 of calibration values is complete, the process of calibration can end. As can be appreciated by one of skill in the art after consideration of the present disclosure, the calibration process can be performed for all of the pixels 104 within the image sensor 100 array 108, sequentially or simultaneously. Alternatively, the calibration process can be performed for a single, representative pixel 104. In accordance with still other embodiments, the calibration process can be performed for a single, representative pixel 104 in each of a plurality of areas or regions of the array 108.

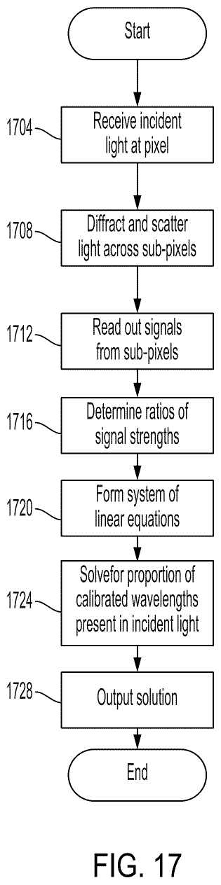

With reference now to FIG. 17, aspects of a method for determining a wavelength of light incident on an image sensor 100 pixel 104 configured and calibrated in accordance with embodiments of the present disclosure are presented. Initially, at step 1704, incident light of an unknown wavelength is received at a pixel 104 configured and calibrated in accordance with embodiments of the present disclosure, and having a set of diffraction features 520 that includes multiple diffraction element layers 524, with each diffraction element layer 524 including multiple transparent diffraction elements 526. The incident light is scattered and diffracted by the diffraction elements 526 in the various diffraction element layers 524, and generates a light intensity spot distribution across the sub-pixels 604 of the pixel 104 as a function of the wavelength of the incident light (1708).

The signals generated by the sub-pixels 604 in response to receiving the incident light are read out (step 1712), and the ratios of signal strengths between pairs of the sub-pixels 604 and selected unique pairs of sub-pixels 604 within the pixel 104 are determined (1716). The wavelength of the incident light can then be determined by forming a system of linear equations, with each equation within the system corresponding to a different pair of sub-pixels (step 1720). For example, where the sensor is calibrated for discerning between twenty-three wavelengths, twenty-three different signal ratios are measured, and these signal ratios are used to form twenty-three equations within a range of from 400 nm to 950 nm. As can be appreciated by one of skill in the art after consideration of the present disclosure, ratios for the same combinations of sub-pixels 604 as were used for calibrating the subject pixel 104 are represented in the equations.

Each equation in the system of equations can have the following form:

(Rn₁n₂)_{λ1}X_{λ1}+(Rn₁n₂)_{λ2}X_{λ2}+ . . . +(Rn₁n₂)_{λy}X_{λy}=Mn₁n₂
where, in the first term, (Rn₁n₂)_{λ1} is the calibrated ratio of a first sub-pixel 604 photodiode signal to a second sub-pixel 604 photodiode signal for light having a first selected wavelength, and X_{λ1} is the unknown contribution of light of the first selected wavelength to the light incident on the pixel. The second term in the equation includes a ratio of the same two sub-pixels 604 as the first term, but at a second selected wavelength, and includes the unknown contribution of light of the second selected wavelength to the light incident on the pixel. Each of the succeeding terms follows this same pattern. Accordingly, a term is provided for each calibrated wavelength, where each calibrated wavelength is separated from a neighboring calibrated wavelength by an amount equal to a desired wavelength determination resolution, from one end of the range of calibrated wavelengths to the other. The sum of the included terms is equal to the ratio of the signals generated by the first and second sub-pixels 604 in response to their exposure to the incident light of an unknown wavelength.

The system of equations can then be solved for the unknowns, yielding the proportions or relative contributions of the calibrated wavelengths to the light received at the subject pixel (step 1724).

Solving the system of equations results in a solution vector as follows:

$$( \begin{matrix}{X}_{λ 1} \\ {X}_{λ 2} \\ ⋮ \\ {X}_{λ y}\end{matrix} )$$

where a value X is determined for each of the y calibrated wavelengths, thus providing a value or proportion for each wavelength component in the incident light. The determined proportions can then be provided as an output that also includes a measure of the intensity of the intensity of the light at the pixel 104, which is given by the sum of the signals from the included sub-pixels 604 (step 1728). The process can be repeated for each pixel 104 in the array 108. According to this method, one equation is provided for each of a number of different sub-pixel 604 signal ratios. More particularly, one equation can be created for each step of resolution over the effective wavelength determination range of the image sensor 100.

Accordingly, continuing an example in which a wavelength determination resolution of 25 nm over a range of 400 nm to 950 nm is desired, and where each pixel 104 includes nine sub-pixels 604, an equation for twenty-three of the thirty-six unique signal ratio combinations that are possible can be created. The resulting system of twenty-three equations can thus be expressed as follows:

$$\begin{matrix}R {14}_{400} {X}_{400} + R 1 {4}_{425} {X}_{425} + … + R 1 {4}_{950} {X}_{950} = M 14 \\ R {15}_{400} {X}_{400} + R 1 {5}_{425} {X}_{425} + … + R 1 {5}_{950} {X}_{950} = M 15 \\ R {16}_{400} {X}_{400} + R 1 {6}_{425} {X}_{425} + … + R 1 {6}_{950} {X}_{950} = M 16 \\ ⋮ \\ R {58}_{400} {X}_{400} + R {58}_{425} {X}_{425} + … + R {58}_{950} {X}_{950} = M 58\end{matrix}$$

The solution of this system of equations is the following solution vector:

$$( \begin{matrix}{X}_{400} \\ {X}_{450} \\ ⋮ \\ {X}_{950}\end{matrix} )$$

which yields values for the relative proportions of light within the calibrated wavelengths included in the light received at the pixel 104.

Accordingly, embodiments of the present disclosure enable the wavelength of light incident on a pixel 104 to be determined without requiring the use of color or wavelength selective filters. Therefore, the sensitivity of an image sensor 100 incorporating pixels 104 as disclosed herein can be greater than conventional color sensing devices. In addition, the wavelength resolution of an image sensor 100 including pixels 104 as disclosed herein can be relatively high. As a further advantage, the stack height of the pixel 104 structures disclosed herein are relatively low. Moreover, embodiments of the present disclosure enable a wavelength determining image sensor 100 to be created using only CMOS processes.

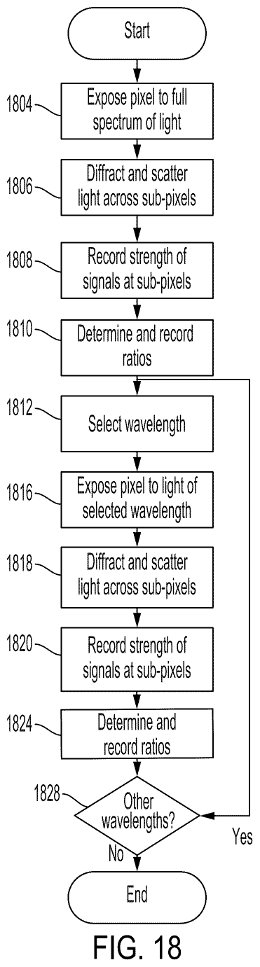

As another method for determining a wavelength of light incident on a pixel 104 in accordance with embodiments of the present disclosure, a system of multiple 2×2 matrices can be created and solved. As in other embodiments, this further method includes a calibration process. Aspects of a calibration process that can be performed in connection with such a method are depicted in FIG. 18, which can begin with exposing a pixel 104 to a full spectrum or wideband light source (step 1804). In particular, the full spectrum light source can simultaneously provide light over a range of wavelengths of interest for calibration. For instance, the full spectrum light source can provide light from about 400 nm to about 950 nm where wavelengths within a range of from 400 nm to 950 nm are to be calibrated. The full spectrum light is diffracted and scattered across the sub-pixels 604 of the pixel 104 (step 1806). The strength of the signals at each of the sub-pixels 604 within the pixel 104 as a result of the exposure to the full spectrum light source are then recorded (step 1808). The ratios of signal strengths between pairs of sub-pixels 604 within the pixel are then determined and recorded (step 1810).

The process can then continue with a selection of a specific wavelength or center wavelength (step 1812). The pixel 104 is then exposed to light of the selected wavelength (step 1816). In accordance with at least some embodiments of the present disclosure, exposing the pixel 104 to light of a selected wavelength can include exposing the pixel to a relatively narrow band of wavelengths centered on the selected wavelength. For example, where the image sensor 100 is calibrated for a wavelength determination resolution of 25 nm, the light of the selected wavelength can extend for about 15 nm on either side of the selected wavelength. Accordingly, the wavelength band of light about a given selected wavelength can partially overlap with the wavelength band of light about a next or neighboring selected wavelength. The light of the selected wavelength is diffracted and scattered across the sub-pixels 604 of the pixel 104 (step 1818). The strength of the signals produced at each of the sub-pixels 604 as a result of the exposure to the light of the selected wavelength is then recorded (step 1820). The ratios of signal strengths between pairs of sub-pixels 604 within the pixel are then determined and recorded (step 1824).

At step 1828, a determination is made as to whether calibration for other selected wavelengths is required or desired. If so, the process can return to step 1812. Otherwise, the calibration process is considered complete and can end. In accordance with embodiments of the present disclosure, at least four unique signal ratio pairs are recorded for each calibration (full spectrum or selected wavelength). Accordingly, it is possible to calibrate even a pixel 104 having a 2×2 array of sub-pixels 604 for an arbitrarily fine wavelength determination resolution using such a methodology.

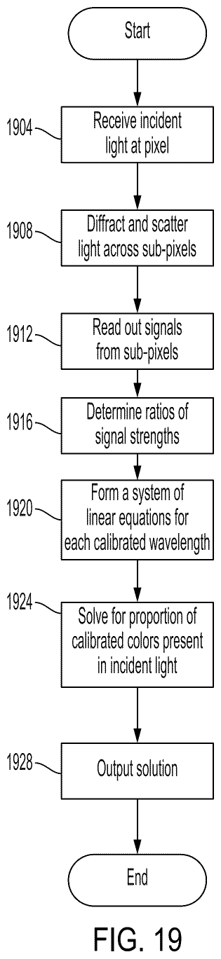

With reference now to FIG. 19, aspects of a process for determining a wavelength of light incident on a pixel 104 in accordance with embodiments of the present disclosure that has been calibrated according to a process as discussed in connection with FIG. 18 are depicted. Initially, at step 1904, incident light is received at a calibrated pixel 104 of an image sensor 100. The incident light is diffracted and scattered across the sub-pixels 604 of the pixel 104 by the associated set of diffraction features 520 (step 1908). The signals generated by the sub-pixels 604 as a result of the exposure to the incident light are then read out and can be stored (step 1912). Ratios of signal strengths for a number of pairs of sub-pixels 604 are then determined (step 1916). In accordance with embodiments of the present disclosure, the pairs of sub-pixels 604 for which signal ratios are determined includes at least those pairs of sub-pixels 604 for which signal ratios were determined during the corresponding calibration process for the pixel 104 (i.e. the process discussed in connection with FIG. 18).

A system of linear equations is then formed using the measured sub-pixel 604 signals and the determined signal ratios from the exposure of the pixel 104 to the light (step 1920). In accordance with embodiments of the present disclosure, the system of equations includes a set or sub-system of two linear equations for each of the calibrated wavelengths. A first one of the equations can have the following form:

Measured FR1=FR1_{λ}*X_{λ}+FR1_{Spectrum}*X_{Spectrum}

A second one of the equations can have the following form:

Measured FR2=FR2_{λ}*X_{λ}+FR2_{Spectrum}*X_{Spectrum}

In these equations, Measured FR1 is the ratio of signal strengths obtained from a first set of selected sub-pixel 604 signal ratios obtained by exposing the pixel 104 to light of the unknown wavelength, Measured FR2 is the ratio of signal strengths obtained from a second set of selected sub-pixel 604 signal ratios obtained by exposing the pixel 104 to light of the unknown wavelength, FR1_{Spectrum} is formed using the first set of selected sub-pixel 604 signal ratios obtained as a result of the exposure of the pixel 104 to full spectrum light during the calibration process, while FR2_{Spectrum} is formed using the second set of selected sub-pixel 604 signal ratios obtained as a result of the exposure of the pixel 104 to full spectrum light during the calibration process. The first set of selected sub-pixel 604 signal ratios differs from the second set of selected sub-pixel 604 signal ratios. FR1, is formed using the first set of selected sub-pixel 604 signal ratios obtained for a selected wavelength obtained during the calibration process, while FR2_{λ} is formed using the second set of selected sub-pixel 604 ratios obtained during the calibration process for that same wavelength. Accordingly, the sub-pixel 604 ratios selected for the first set are the same pairs of sub-pixels 604 used to form FR1_{Spectrum}, and the sub-pixel 604 ratios selected for the second set are the same pairs of sub-pixels 604 used to form FR2_{Spectrum}. X_{λ} is the amount of the signal in the incident light of a selected wavelength. X_{Spectrum} is the amount to the signal if the full calibration light spectrum was incident on the pixel.
For example, FR1_{Spectrum} can be constructed as follows:

FR1_{Spectrum}=(R₁₄)²−R₁₄*R₂₃+(R₂₃)²

FR2_{Spectrum} can be constructed as follows:

FR2_{Spectrum}(R₁₅)²−R₁₅*R₃₄+(R₃₄)²

FR1_{λ} can be constructed as follows:

FR1_{λ1}=(R₁₄)²−R₁₄*R₂₃+(R₂₃)²

and FR2_{λ} can be constructed as follows:

FR2_{λ}=(R₁₅)²−R₁₅*R₃₄+(R₃₄)²

In these examples, the notation R_{#1 #2} indicates the pair of sub-pixels 604 used to form the ratio. Continuing the example of a system 100 providing a wavelength determination resolution of 25 nm over a range of 400 nm to 950 nm, 23 such sets of linear equations are formed, with each set including calibration information obtained for one of 23 selected wavelengths.

Each 2×2 system is then solved for the proportion of a selected wavelength to the received signal (step 1924). Further continuing the example of a system 100 providing a wavelength determination resolution of 25 nm over a range of 400 nm to 950 nm, the system of equations for each of 23 wavelengths (i.e. each wavelength from 400 nm to 950 nm inclusive, in steps of 25 nm) is solved. The contribution of light of different wavelengths across the entire calibrated range can then be recovered, as the values obtained from the solutions of the different systems of equations indicate the proportion of each of the different wavelengths to the total signal. The determined proportions can then be provided as an output from the system 100 (step 1928).

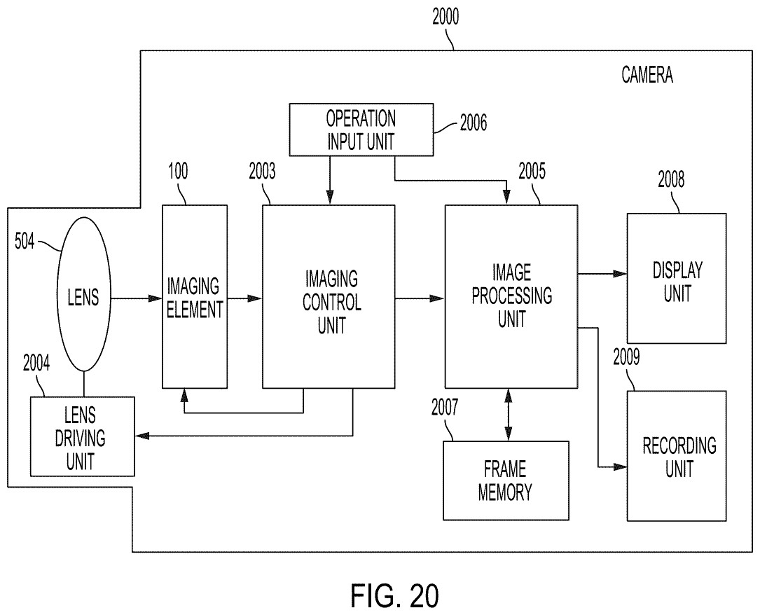

FIG. 20 is a block diagram illustrating a schematic configuration example of a camera 2000 that is an example of an imaging apparatus to which a system 500, and in particular an image sensor 100, in accordance with embodiments of the present disclosure can be applied. As depicted in the figure, the camera 2000 includes an optical system or lens 504, an image sensor 100, an imaging control unit 2003, a lens driving unit 2004, an image processing unit 2005, an operation input unit 2006, a frame memory 2007, a display unit 2008, and a recording unit 2009.

The optical system 504 includes an objective lens of the camera 2000. The optical system 504 collects light from within a field of view of the camera 2000, which can encompass a scene containing an object. As can be appreciated by one of skill in the art after consideration of the present disclosure, the field of view is determined by various parameters, including a focal length of the lens, the size of the effective area of the image sensor 100, and the distance of the image sensor 100 from the lens. In addition to a lens, the optical system 504 can include other components, such as a variable aperture and a mechanical shutter. The optical system 504 directs the collected light to the image sensor 100 to form an image of the object on a light incident surface of the image sensor 100.

As discussed elsewhere herein, the image sensor 100 includes a plurality of pixels 104 disposed in an array 108. Moreover, the image sensor 100 can include a semiconductor element or substrate 112 in which the pixels 104 each include a number of sub-pixels 604 that are formed as photosensitive areas or photodiodes within the substrate 112. In addition, as also described elsewhere herein, each pixel 104 is associated with a set of diffraction features 520 formed in a diffraction element layer 524 positioned between the optical system 504 and the sub-pixels 604. The photosensitive sites or sub-pixels 604 generate analog signals that are proportional to an amount of light incident thereon. These analog signals can be converted into digital signals in a circuit, such as a column signal processing circuit 120, included as part of the image sensor 100, or in a separate circuit or processor. As discussed herein the distribution of light amongst the sub-pixels 604 of a pixel 104 is dependent on the light state of the incident light. The digital signals can then be output.

The imaging control unit 2003 controls imaging operations of the image sensor 100 by generating and outputting control signals to the image sensor 100. Further, the imaging control unit 2003 can perform autofocus in the camera 2000 on the basis of image signals output from the image sensor 100. Here, “autofocus” is a system that detects the focus position of the optical system 504 and automatically adjusts the focus position. For example, a method in which an image plane phase difference is detected by phase difference pixels arranged in the image sensor 100 to detect a focus position (image plane phase difference autofocus) can be used. Further, a method in which a position at which the contrast of an image is highest is detected as a focus position (contrast autofocus) can also be applied. The imaging control unit 2003 adjusts the position of the lens 1001 through the lens driving unit 2004 on the basis of the detected focus position, to thereby perform autofocus. Note that, the imaging control unit 2003 can include, for example, a DSP (Digital Signal Processor) equipped with firmware.

The lens driving unit 2004 drives the optical system 504 on the basis of control of the imaging control unit 2003. The lens driving unit 2004 can drive the optical system 504 by changing the position of included lens elements using a built-in motor.

The image processing unit 2005 processes image signals generated by the image sensor 100. This processing includes, for example, assigning a light state to light incident on a pixel 104 by determining ratios of signal strength between pairs of sub-pixels 604 included in the pixel 104, and determining an amplitude of the pixel 104 signal from the individual sub-pixel 604 signal intensities, as discussed elsewhere herein. In addition, this processing includes determining a color of light incident on a pixel 104 by applying the observed ratios of signal strengths from pairs of sub-pixels 604 and calibrated ratios for those pairs stored in a calibration table 1204 to solve a system of equations. The image processing unit 2005 can include, for example, a microcomputer equipped with firmware, and/or a processor that executes application programming, to implement processes for identifying color information in collected image information as described herein.

The operation input unit 2006 receives operation inputs from a user of the camera 2000. As the operation input unit 2006, for example, a push button or a touch panel can be used. An operation input received by the operation input unit 2006 is transmitted to the imaging control unit 2003 and the image processing unit 2005. After that, processing corresponding to the operation input, for example, the collection and processing of imaging an object or the like, is started.

The frame memory 2007 is a memory configured to store frames that are image signals for one screen or frame of image data. The frame memory 2007 is controlled by the image processing unit 2005 and holds frames in the course of image processing.

The display unit 2008 can display information processed by the image processing unit 2005. For example, a liquid crystal panel can be used as the display unit 2008.

The recording unit 2009 records image data processed by the image processing unit 2005. As the recording unit 2009, for example, a memory card or a hard disk can be used.

An example of a camera 2000 to which embodiments of the present disclosure can be applied has been described above. The image sensor 100 of the camera 2000 can be configured as described herein. Specifically, the image sensor 100 can diffract incident light across different light sensitive areas or sub-pixels 604 of a pixel 104, and can apply ratios of signals from pairs of the sub-pixels 604 to and corresponding stored ratios for a number of different colors, to identify relative contributions of constituent colors, and thus the color of the incident light.

Note that, although a camera has been described as an example of an electronic apparatus, an image sensor 100 and other components, such as processors and memory for executing programming or instructions and for storing calibration information as described herein, can be incorporated into other types of devices. Such devices include, but are not limited to, surveillance systems, automotive sensors, scientific instruments, medical instruments, etc. In accordance with still other embodiments, a system 100 as disclosed herein be implemented in connection with a communication system, in which information is encoded or is distinguished from other units of information using the wavelength and polarization state of light. Still other applications of embodiments of the present disclosure include quantum computing.

As can be appreciated by one of skill in the art after consideration of the present disclosure, an image sensor 100 as disclosed herein utilizes interference effects to obtain wavelength information. In addition, an image sensor 100 as disclosed herein can be produced using CMOS processes entirely. Implementations of an image sensor 100 or devices incorporating an image sensor 100 as disclosed herein can utilize calibration tables developed for each pixel 104 of the image sensor 100. Alternatively, calibration tables can be developed for each different pattern of diffraction element sets 520. In addition to providing calibration tables that are specific to particular pixels 104 and/or particular patterns of diffraction features 524, calibration tables an be developed for use in selected regions of the array 108, or can be applied to all of the pixels 104 within the array 108.

Methods for producing an image sensor 100 in accordance with embodiments of the present disclosure include applying conventional CMOS production processes to produce an array of pixels 104 in an image sensor substrate 112 in which each pixel 104 includes a plurality of sub-pixels or photodiodes 604. As an example, the material of the sensor substrate 112 is silicon (Si), and each sub-pixel 604 is a photodiode formed therein. A thin layer of material or grating substrate 528 can be disposed on or adjacent a light incident side of the image sensor substrate 112. Moreover, the grating substrate 528 can be disposed on a back surface side of the image sensor substrate 112. As an example, the grating substrate is silicon oxide (SiO₂), and has a thickness of 400 nm or less. In accordance with the least some embodiments of the present disclosure, an anti-reflection layer 532 can be disposed between the light incident surface of the image sensor substrate 112 and the grating substrate 528. A set of diffraction features 520 is provided for each of the color sensing pixels 104. The set of diffraction features 520 can be formed as transparent features disposed in multiple layers 524, including in layers configured as trenches formed in the grating substrate 528, and other layers 524 configured as trenches formed in the sensor substrate 112. For example, the diffraction elements 526 in the grating substrate 528 can be formed from TiO2, and diffraction elements 526 in the sensor substrate 112 can be formed from SiO2. The diffraction elements 526 can be relatively thin (i.e. from about 100 to about 200 nm), and the pattern can include a plurality of linear diffraction elements 526 of various lengths disposed along lines that extend radially from a central area of a pixel 104. Production of an image sensor 100 in accordance with embodiments of the present disclosure can be accomplished using only CMOS processes. Moreover, an image sensor produced in accordance with embodiments of the present disclosure does not require micro lenses or color filters for each pixel.

The foregoing has been presented for purposes of illustration and description. Further, the description is not intended to limit the disclosed systems and methods to the forms disclosed herein. Consequently, variations and modifications commensurate with the above teachings, within the skill or knowledge of the relevant art, are within the scope of the present disclosure. The embodiments described hereinabove are further intended to explain the best mode presently known of practicing the disclosed systems and methods, and to enable others skilled in the art to utilize the disclosed systems and methods in such or in other embodiments and with various modifications required by the particular application or use. It is intended that the appended claims be construed to include alternative embodiments to the extent permitted by the prior art.

What is claimed is:

1. A method, comprising:
receiving light at a pixel of an image sensor;
diffracting the received light onto a plurality of sub-pixels included in the pixel, wherein the received light is diffracted by a set of diffraction features, and wherein the set of diffraction features includes a plurality of diffraction element layers that each include a plurality of transparent diffraction elements;
determining a ratio of a signal strength generated by the sub-pixels for a plurality of unique pairs of the sub-pixels;
forming a plurality of linear equations, wherein each linear equation in the plurality of linear equations includes terms based on the determined sub-pixel signal strength ratios for each of a plurality of different calibrated wavelengths; and
solving a system including the plurality of linear equations, wherein a proportion of light at each of the plurality of different calibrated wavelengths within the received light is determined.

2. The method of claim 1, wherein forming a plurality of linear equations includes:
forming one equation for each of a plurality of unique pairs of sub-pixel signal strength ratios, wherein each of the equations includes a sum of a plurality of terms, wherein each term in the plurality of terms is formed for a different selected one of a plurality of calibrated wavelengths and includes a calibrated ratio of the pair of sub-pixel signal strength ratios of that equation at a selected one of the plurality of calibrated wavelengths multiplied by an unknown contribution of a signal strength at the pixel from light at the selected one of the plurality of calibrated wavelengths, and wherein the sum of the plurality of terms is set equal to the determined ratio of a signal strength for the pair of sub-pixel signal ratios.

3. The method of claim 2, wherein the system of linear equations includes one linear equation for each of the plurality of calibrated wavelengths.

4. The method of claim 3, wherein each linear equation in the system of linear equations has the form:
(Rn₁n₂)_{λ1}X_{λ1}+(Rn₁n₂)_{λ2}X_{λ2}+ . . . +(Rn₁n₂)_{λy}X_{λy}=Mn₁n₂
where, in the first term, (Rn₁n₂)_{λ1} is the calibrated ratio of a first sub-pixel photodiode signal to a second sub-pixel photodiode signal for light having a first selected wavelength (λ₁), and X_{λ1} is the unknown contribution of light of the first selected wavelength (λ₁) to the light incident on the pixel, where, in the second term, (Rn₁n₂)_{λ2} is the calibrated ratio of the first sub-pixel photodiode signal to the second sub-pixel photodiode signal for light having a second selected wavelength (λ₂), and X_{λ2} is the unknown contribution of light of the second selected wavelength (λ₂) to the light incident on the pixel, where this pattern is repeated until a final term, where (Rn₁n₂)_{λy} is the calibrated ratio of the first sub-pixel photodiode signal to the second sub-pixel photodiode signal for light having a y^{th} selected wavelength (λ_{y}), and X_{λy} is the unknown contribution of light of the y^{th} selected wavelength (λ_{y}) to the light incident on the pixel, and where Mn₁n₂ is the measured ratio of the first sub-pixel photodiode signal to the second sub-pixel photodiode signal from the light incident on the pixel.

5. The method of claim 1, wherein forming a plurality of linear equations includes forming a plurality of sets of linear equations, wherein each set of linear equations includes sub-pixel signal ratios for a different one of the calibrated wavelengths.

6. The method of claim 5, wherein each of the sets of linear equations includes a value of signal ratios for a set of selected sub-pixel signal ratios.

7. The method of claim 6, wherein each of the sets of linear equations includes sub-pixel signal ratios for a full spectrum signal.

8. The method of claim 7, wherein solving the system including the plurality of linear equations includes solving each of the plurality of sets of linear equations, wherein a solution to each set yields a proportion of light incident on the pixel that includes light of the calibrated wavelength included in that set.

9. The method of claim 1, wherein the pixel includes at least nine sub-pixels.

10. The method of claim 9, wherein each of the calibrated wavelengths are separated from one another by about 25 nm.

11. A sensor, comprising:
a sensor substrate;
a grating substrate, wherein the grating substrate is disposed on a light incident surface side of the sensor substrate; and
a pixel disposed in the sensor substrate, wherein the pixel includes a plurality of sub-pixels; and
a set of diffraction elements for the pixel, wherein the diffraction elements are disposed in a plurality of layers, including a plurality of diffraction element layers disposed in the grating substrate and at least a first diffraction element layer disposed in the grating substrate.

12. The sensor of claim 11, wherein the sensor includes nine sub-pixels disposed in a 3×3 array.

13. The sensor of claim 11, wherein the diffraction elements are transparent.

14. The sensor of claim 11, wherein the diffraction elements are configured to at least one of diffract and scatter incident light across the sub-pixels of the pixel.

15. The sensor of claim 11, wherein the diffraction elements each have a refractive index that is higher than a refractive index of the substrate in which the diffraction elements are formed.

16. The sensor of claim 15, wherein at least some of the diffraction elements are formed from a first material, and wherein others of the diffraction elements are formed from a second material.

17. The sensor of claim 11, wherein the diffraction element layers include a diffraction element layer disposed in the grating substrate and adjacent a light incident surface side of the grating substrate, a diffraction element layer disposed in the grating substrate and adjacent a surface opposite the light incident surface side of the grating substrate, and a diffraction element layer disposed in the sensor substrate adjacent a light incident surface of the sensor substrate.

18. The sensor of claim 11, further comprising:
an antireflective coating, wherein the antireflective coating is between the sensor substrate and the grating.

19. The sensor of claim 11, wherein a thickness of the grating substrate is less than 350 nm.

20. An imaging device, comprising:
an image sensor, including:
a sensor substrate;
a plurality of pixels formed in the sensor substrate, wherein each pixel in the plurality of pixels includes a plurality of sub-pixels;
a grating substrate disposed on a light incident surface side of the sensor substrate; and
a plurality of sets of diffraction features, wherein each pixel in the plurality of pixels is associated with one set of the diffraction features, and wherein each set of diffraction features includes a plurality of diffraction element layers that each include a plurality of diffraction elements, wherein at least a first one of the diffraction element layers is formed in the grating substrate, and wherein at least a second one of the diffraction element layers is formed in the sensor substrate;
an imaging lens, wherein light collected by the imaging lens is incident on the image sensor, and wherein the sets of diffraction features diffract and scatter the incident light onto the sub-pixels of the respective pixels; and
a processor, wherein the processor executes application programming, wherein the application programming determines a wavelength of light incident on a selected pixel from ratios of a relative strength of a signal generated at different pairs of sub-pixels of the selected pixel in response to the light incident on the selected pixel.
